(19) United States
(12) Patent Application Publication
(10) Pub. No.: US 2019/0206686 A1
(43) Pub. Date: Jul. 4, 2019

(54) COMPONENT FOR FABRICATING SIC SEMICONDUCTOR, HAVING PLURALITY OF LAYERS HAVING DIFFERENT TRANSMITTANCES, AND METHOD FOR MANUFACTURING SAME

(71) Applicant: TOKAI CARBON KOREA CO., LTD., ANSEONG-SI (KR)

(72) Inventor: JOUNG IL KIM, SEOUL (KR)

(73) Assignee: TOKAI CARBON KOREA CO., LTD., ANSEONG-SI (KR)

(21) Appl. No.: 16/325,877

(22) PCT Filed: Aug. 18, 2017
(86) PCT No.: PCT/KR2017/009001

§ 371 Date: Feb. 15, 2019

(30) Foreign Application Priority Data
Aug. 18, 2016 (KR) 10 2016 0104727
Aug. 17, 2017 (KR) 10 2017 0104300

(51) Int. Cl. H01L 21/205; H01L 21/3065; H01L 21/3213; H01L 21/02; H01L 29/24; H01L 21/311

(52) U.S. Cl. CPC H01L 21/205; H01L 21/3065; H01L 21/31116; H01L 21/02378; H01L 29/24; H01L 21/32136

(57) ABSTRACT

Provided according to an embodiment of the present invention is a component for fabricating an SiC semiconductor, having a plurality of layers having different transmittances, the component comprising two or more superposed layers, wherein each of the superposed layers contains SiC and has a transmittance value different from that of another adjacent layer.

### TECHNICAL FIELD

The present invention relates to a component for fabricating an SiC semiconductor which manufactures a semiconductor device using a substrate such as a wafer, in a dry etching process, and a manufacturing method therefor, and more particularly, to a component for fabricating an SiC semiconductor having a plurality of layers having different transmittances and a manufacturing method therefor.

### BACKGROUND

Generally, a plasma processing technique used in a semiconductor manufacturing process is one of dry etching processes, in which a target is etched using gas. The plasma processing technique follows a process of physically and chemically removing a wafer surface by injecting an etching gas into a reaction vessel, ionizing the etching gas, and then accelerating the etching gas onto the wafer surface. This method is widely used because it is easy to control the etching, has a high productivity, and forms fine patterns of several tens of nanometers.

Parameters which need to be considered for uniform etching in the plasma etching include a thickness and a density of a layer to be etched, an energy and a temperature of the etching gas, adhesiveness of a photoresist, a state of a wafer surface, and uniformity of the etching gas. Specifically, controlling of a radio frequency (RF) which is a driving force for ionizing the etching gas and accelerating the ionized etching gas onto the wafer surface to perform the etching may be an important parameter and is also considered as a parameter which can be directly and easily controlled during an actual etching process.

However, in practice, with respect to a wafer which is actually etched in the dry etching device, it is essential to uniformly apply a radio frequency so that the energy is uniformly distributed on the entire wafer surface. Further, the application of the uniform energy distribution at the time of applying the radio frequency cannot be achieved only by controlling an output of the radio frequency. In order to solve the above-mentioned problem, it highly depends on a shape of a stage and an anode serving as radio frequency electrodes used to apply the radio frequency to the wafer and components for fabricating a semiconductor including a focus ring serving to substantially fix the wafer.

Various components for fabricating a semiconductor including a focus ring in the dry etching device play a role to cause plasma to be concentrated around a wafer on which an etching process is performed in a reaction vessel under a severe condition where plasma exists and the components themselves are exposed to the plasma to be damaged. Accordingly, researches to enhance plasma resistance of the components for fabricating a semiconductor have been consistently carried out. As one of them, there is a research for a method for manufacturing a component such as a focus ring or an electrode formed of an SiC material, instead of Si material.

According to the related art, a plurality of injecting introduction holes is configured in a chamber for the purpose of a process efficiency and uniform deposition and the injecting introduction holes are simultaneously used to manufacture a component for fabricating an SiC semiconductor.

FIG. 1 is a cross-section view of one of components for fabricating an SiC semiconductor manufactured by simultaneously using a plurality of raw material gas injecting introduction holes. The raw material gas is deposited on a base material in the chamber to finally form a component 200 for fabricating an SiC semiconductor as illustrated in FIG. 1.

FIG. 2 is a scanning electron microscope (SEM) analysis photograph of a component for fabricating an SiC semiconductor manufactured according to the related art. Bright color represents a crystal structure of an SiC abnormal structure. It is identified that the abnormal structure was conically grown during an SiC deposition process. A quality of the component for fabricating an SiC semiconductor manufactured by the method of the related art may be degraded due to the above-mentioned growth of the structure.

Further, even though Si is replaced with an SiC material, it is exposed to the plasma after a predetermined period to be worn out, so that periodic replacement is still required. Further, the replaced components were discarded as they were after being replaced. It was considered as one of major causes to increase a production cost of the semiconductor products.

### SUMMARY OF THE INVENTION

### Technical Problem

The present invention is made to solve the above-mentioned problem and provides a component for fabricating an SiC semiconductor having an excellent quality by suppressing the growth of abnormal crystal of the component for fabricating an SiC semiconductor and inducing uniform deposition from a raw material gas injecting introduction hole. Further, for example, the present invention contributes to environmental preservation by reducing the industrial wastes generated due to the disposal of consumable components for fabricating an SiC semiconductor, such as a replaced focus ring and reduces a production cost of the final semiconductor product.

However, technical problems to be solved by the present invention are not limited to the above-mentioned technical problems, and other technical problems, which are not mentioned above, can be clearly understood by those skilled in the art from the following descriptions.

### Technical Solution

According to an exemplary embodiment of the present invention, a component for fabricating an SiC semiconductor having a plurality of layers having different transmittances, includes two or more superposed layers and each of superposed layers contains SiC and has a transmittance value different from that of another adjacent layer.

According to an exemplary embodiment of the present invention, a color may be gradually changed at a boundary of superposed layers.

According to an exemplary embodiment of the present invention, compositions of the superposed layers may be the same.

According to an exemplary embodiment of the present invention, the superposed layers may be superposed on a graphite base material.

According to an exemplary embodiment of the present invention, interception of growth of one or more abnormal crystals may be included in the boundary of superposed layers.

According to an exemplary embodiment of the present invention, the component for fabricating a semiconductor may be a component of a plasma processing device and include at least one selected from a group consisting of a ring, an electrode, and a conductor.

According to an exemplary embodiment of the present invention, the component for fabricating an SiC semiconductor may further include a regenerating unit containing SiC formed on at least a part of the superposed layer.

According to an exemplary embodiment of the present invention, colors between the regenerating unit containing SiC and a superposed layer adjacent to the regenerating unit may be different.

According to another exemplary embodiment of the present invention, a manufacturing method of a component for fabricating an SiC semiconductor includes, in a chemical vapor deposition chamber including a plurality of raw material gas injecting introduction holes, superposing a first layer containing SiC using a first introduction hole group including some of the plurality of raw material gas injecting introduction holes; and superposing a second layer containing SiC using a second introduction hole group including the other some of the plurality of raw material gas injecting introduction holes.

According to an exemplary embodiment of the present invention, the method may further include, after the superposing of a second layer, superposing a third layer containing SiC using a third introduction hole group.

According to an exemplary embodiment of the present invention, between the superposing of layers, the component for fabricating an SiC semiconductor may be maintained in a chemical vapor deposition chamber.

According to an exemplary embodiment of the present invention, in the chemical vapor deposition chamber, locations of introduction hole groups may be different.

According to an exemplary embodiment of the present invention, times to perform the superposing of layers may be different.

According to an exemplary embodiment of the present invention, the method may further include: processing plasma on the component for fabricating an SiC semiconductor in a dry etching device; and forming a regenerating unit containing SiC on at least a part of the superposed layer of the component for fabricating an SiC semiconductor.

According to an exemplary embodiment of the present invention, an average thickness of the regenerating unit may be 0.1 mm to 3 mm.

According to an exemplary embodiment of the present invention, the method may further include, between the processing of plasma and the forming of a regenerating unit, processing the component for fabricating an SiC semiconductor, a pre-cleaning step, or both the processing and the pre-cleaning step.

According to an exemplary embodiment of the present invention, the method may further include, after the forming of a regenerating unit, a post-processing step of the formed regenerating unit, a post-cleaning step, or both the steps.

### Effects

A component for fabricating an SiC semiconductor having a plurality of layers having different transmittances according to an exemplary embodiment of the present invention suppresses excessive growth of an abnormal crystal to prevent the deterioration of inherent physical properties of a material including a plasma resistance. Further, it is possible to prevent degradation of a quality of a product due to the deposition of the raw material gas inside the introduction hole during the manufacturing process of the component for fabricating an SiC semiconductor. Further, a component for fabricating an SiC semiconductor having a plurality of layers having different transmittances according to an exemplary embodiment of the present invention has the same effect as the replacement of a new product only by forming a new regenerating unit on a surface of the component for fabricating a semiconductor etched by the plasma so that a cost for replacing a consumable component of the related art may be saved.

### BRIEF DESCRIPTION OF DRAWINGS

FIG. 1 is a cross-section view of one of components for fabricating an SiC semiconductor manufactured by simultaneously using a plurality of raw gas injecting introduction holes.

FIG. 2 is a scanning electron microscope (SEM) analysis photograph of a component for fabricating an SiC semiconductor manufactured according to the related art.

FIG. 3 is a cross-sectional view of a component for fabricating an SiC semiconductor having a plurality of layers having different transmittances according to an exemplary embodiment of the present invention.

FIG. 4 is a photograph of a cross-section of a component for fabricating an SiC semiconductor having a plurality of layers having different transmittances according to an exemplary embodiment of the present invention.

FIG. 5A is a cross-sectional view of an etched state of a component for fabricating an SiC semiconductor having a plurality of layers having different transmittances according to an exemplary embodiment of the present invention which is used in a plasma exposed environment.

FIG. 5B is a cross-sectional view of a component for fabricating an SiC semiconductor having a plurality of layers having different transmittances according to an exemplary embodiment of the present invention which is etched in a plasma exposed environment and has a regenerating unit formed thereafter.

FIG. 6 is a view of a process of manufacturing a component for fabricating an SiC semiconductor having a plurality of layers having different transmittances according to an exemplary embodiment of the present invention.

FIG. 7 is a view of a process of manufacturing a component for fabricating an SiC semiconductor having a plurality of layers having different transmittances according to another exemplary embodiment of the present invention.

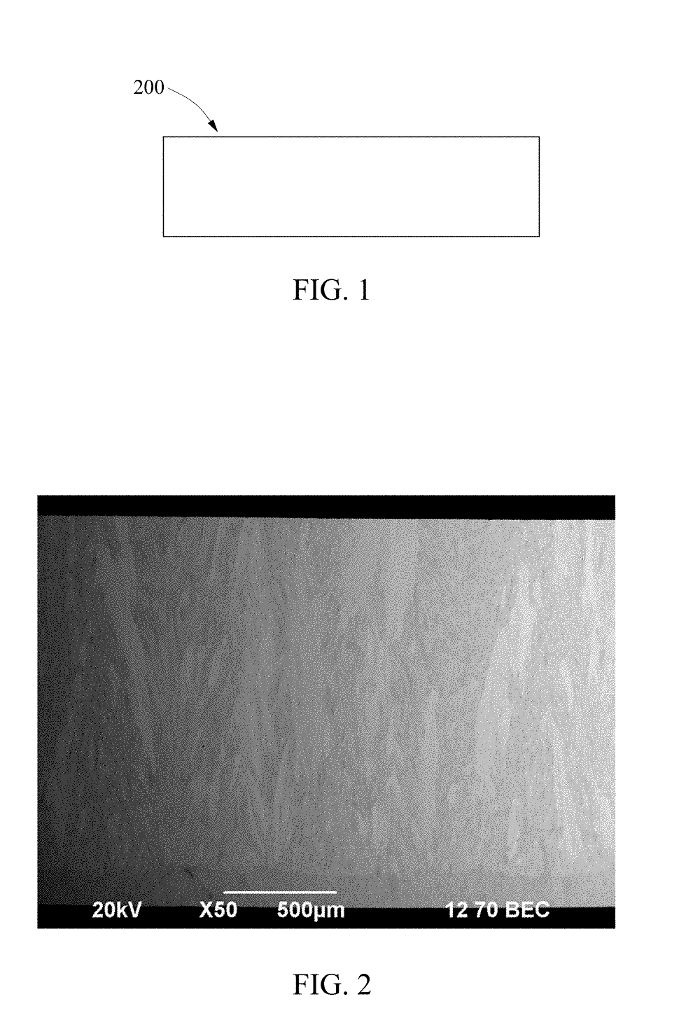

### BEST MODE FOR CARRYING OUT THE INVENTION

Hereinafter, exemplary embodiments of a component for fabricating an SiC semiconductor of the present invention and a manufacturing method therefor will be described in detail with reference to the accompanying drawings. Various modifications may be made to the embodiments and drawings described below. Further, like reference numeral denotes like component regardless of the reference numeral and redundant description thereof will be omitted. It should be understood that exemplary embodiments to be described below are not intended to limit the examples, but include all changes, equivalents, and alternatives to them. In the following description of the exemplary embodiment, a detailed description of known configurations or functions incorporated herein will be omitted when it is determined that the detailed description may make the subject matter of the present disclosure unclear.

Further, terms used in the present description are used in order to appropriately represent preferred embodiments of the present invention and may be construed in different ways according to the intention of users or operators, or customary practice in the art to which the present invention pertains. Therefore, the definitions of terms used in the present description should be construed based on the contents throughout the specification. In each of the drawings, like reference numerals denote like elements.

Through the specification of the present disclosure, when one member is located “on” the other member, the member may be adjacent to the other member or a third member may be disposed between the above two members.

In the specification, unless explicitly described to the contrary, the word “comprise” and variations such as “comprises” or “comprising”, will be understood to imply the inclusion of stated elements but not the exclusion of any other elements.

According to an exemplary embodiment of the present invention, a component for fabricating an SiC semiconductor having a plurality of layers having different transmittances in which two or more superposed layers are included and each layer of the superposed layers contains SiC and has a different transmittance from that of the other adjacent layer.

A component for fabricating an SiC semiconductor according to the present invention includes two or more layers containing SiC and two or more layers may have different transmittances.

An SiC component is a strong covalent bonding material and has an excellent plasma resistance as well as thermal conductivity, hardness, oxidation resistance, abrasion resistance, and corrosion resistance as compared with other ceramic materials. Further, the SiC component is a material which has excellent properties as a material for fabricating a semiconductor which requires a precise process under a severe condition.

In the present invention, the transmittance refers to a degree that light passes through a material layer and corresponds to a value obtained by dividing the intensity of light passing through the material layer by an intensity of incident light for the material layer. The transmittance may be measured by various methods and may be measured with a distance between a specimen and a light source which is 7 cm or less by manufacturing a specimen having a thickness of 3 mm and using a light source with a luminous intensity of 150 Lux or higher. Since the transmittance varies depending on a thickness, a light source, and a distance between the specimen and the light source, the transmittance may be considered as a relative value with the same thickness.

The transmittance corresponds to a unique characteristic of the material so that even though materials have the same ingredient and composition, the materials may have different transmittances depending on a crystal structure and morphology. A component for fabricating an SiC semiconductor having a plurality of layers having different transmittances according to the present invention may include a plurality of layers having different transmittances.

According to an example of the present invention, colors are gradually changed at a boundary of each layer of the superposed layers. Each of superposed layers may have a different color in addition to the different transmittance. In this case, at the boundaries of the superposed layers, colors are not changed such that the different colors are discretely and segmentally changed to clearly distinguish the boundaries, but may be gradually changed. When the component for fabricating an SiC semiconductor is manufactured by a manufacturing method according to another exemplary embodiment of the present invention described below, the color may be gradually changed at boundaries of the superposed layers.

According to an example of the present invention, the superposed layers may have the same compositions. As long as the superposed layers containing SiC have different transmittances in the present invention, the superposed layers are not specifically limited so that the layers may have the same ingredient and composition or different ingredients and compositions. According to an aspect of the present invention, even though the layers are superposed with the same ingredient and composition, it is possible to provide a component for fabricating an SiC semiconductor having a plurality of layers having different transmittances. The transmittance may be measured by various methods and is measured with a distance between a specimen and a light source which is 7 cm or less by manufacturing a specimen having a thickness of 3 mm and using a light source with a luminous intensity of 150 Lux or higher. Since the transmittance varies depending on a thickness, a light source, and a distance between the specimen and the light source, the transmittance may be considered as a relative value with the same thickness.

According to an example of the present invention, the superposed layer may be superposed on a graphite base material. According to an aspect of the present invention, the component for fabricating an SiC semiconductor may be provided by a method for depositing an ingredient containing SiC using a chemical vapor deposition method, so that a base material may be used as a target to be deposited. In this case, as long as a base material forms a deposited surface, in the present invention, the base material is not specifically limited and may be a graphite material.

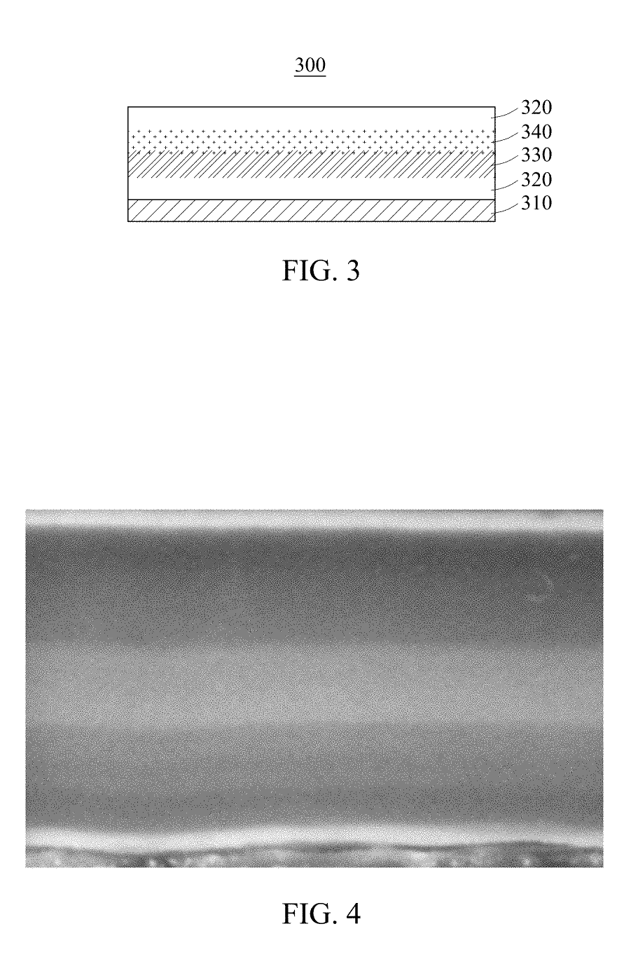

FIG. 3 is a cross-sectional view of a component 300 for fabricating an SiC semiconductor having a plurality of layers having different transmittances according to an exemplary embodiment of the present invention. Referring to FIG. 3, it is illustrated that layers 320, 330, and 340 containing superposed SiC are superposed on a graphite base material 310. Here, the layers 320, 330, and 340 containing SiC may have different transmittances. Further, the boundary of the colors may be clearly formed between the graphite base material 310 and an adjacent layer 320 containing SiC. In contrast, the color may be gradually changed and overlapped at the boundaries 320 and 330, 330 and 340, and 340 and 320 of the superposed layers containing SiC. FIG 4 is a photograph of a cross-section of a component for fabricating an SiC semiconductor having a plurality of layers having different transmittances according to an exemplary embodiment of the present invention. A first layer containing SiC with a clearly distinguished boundary is superposed on the graphite base material. It is understood that a plurality of layers having different SiC having boundaries whose color is gradually changed is superposed thereon.

According to an example of the present invention, at the boundary of the superposed layers, interception of the growth of one or more abnormal crystals may be included. An abnormal crystal structure may be generated in each superposed layer due to impurities or a core formed by a homogeneous reaction. The crystal structure is gradually grown as a component containing SiC is continuously deposited. The abnormal crystal structure grown as described above becomes a major cause to lower inherent physical properties of a material containing SiC. Therefore, it is very important to control the growth of the abnormal crystal structure during a process of manufacturing a product containing SiC by a chemical vapor deposition method.

According to an aspect of the present invention, individual layers are stepwisely formed by intercepting the continuous deposition process of the related art so that the continuous growth of the abnormal crystal structure may be controlled. In this case, the continuous deposition process is intercepted so that the abnormal crystal structure is not continuously grown and a structure in which the growth of the abnormal crystal is intercepted may be formed at the boundary of layers.

According to an example of the present invention, the component for fabricating a semiconductor may include at least one selected from a group consisting of a ring, an electrode, and a conductor, as a component of a plasma processing device. For example, specifically, the component may be a focus ring, an upper electrode, a ground electrode, a shower head, or an outer ring. Any of various components which are exposed to the plasma in the plasma processing device may be included in the component for fabricating an SiC semiconductor of the present invention. Among them, the focus ring, the upper electrode, the ground electrode, and the outer ring are components which are highly likely to be damaged, specifically by the plasma, in the plasma processing device and may correspond to the component for fabricating an SiC semiconductor intended by the present invention.

According to an example of the present invention, a regenerating unit containing SiC formed on at least a part of the superposed layer may be further included. The component for fabricating an SiC semiconductor according to an aspect of the present invention may be used in an environment where the component is exposed to the plasma to be etched. In this case, instead of immediately discarding and replacing it, a regenerating unit containing SiC is newly formed on the damaged portion to be regenerated as a new product. As described above, unlike the components for fabricating a semiconductor of the related art which are handled as consumable components, the component for fabricating an SiC semiconductor including a regenerating unit according to an aspect of the present invention may be reused to lower the production cost of the products.

According to an example of the present invention, the colors are different at the boundary between the regenerating unit containing SiC and the superposed layer adjacent to the regenerating unit. Further, the color is not gradually changed, but discretely and segmentally changed at the boundary of the regenerating unit and the superposed layer adjacent to the regenerating unit. Therefore, the boundary line of the regenerating unit and the superposed layer adjacent to the regenerating unit may be comparatively clearly identified. According to an aspect of the present invention described below, in a manufacturing process for forming respective layers containing SiC, a high temperature may be maintained without being lowered in the chemical vapor deposition chamber even during the process in which the layers are changed. In contrast, during a process of forming the regenerating unit containing SiC, a product completed by superposing the layers is taken out from the chemical vapor deposition chamber to be cooled down and then used in a plasma exposed environment and then a step of forming the regenerating unit containing SiC is performed. During this process, the color may be discretely and segmentally changed at the boundary of the regenerating unit containing SiC and the superposed layer adjacent to the regenerating unit.

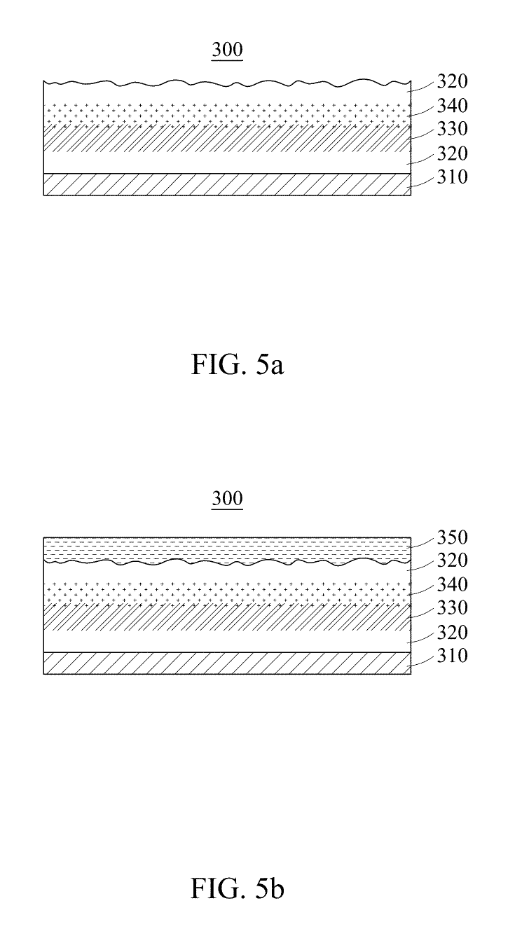

FIG. 5A is a cross-sectional view of an etched state of a component for fabricating an SiC semiconductor having a plurality of layers having different transmittances according to an exemplary embodiment of the present invention which is used in a plasma exposed environment. A top layer 320 among layers containing SiC has a structure which is etched by the plasma to be damaged.

FIG. 5B is a cross-sectional view of a component for fabricating an SiC semiconductor having a plurality of layers having different transmittances according to an exemplary embodiment of the present invention which is etched in a plasma exposed environment and has a regenerating unit 350 formed thereafter. The same effect that a new product is produced may be obtained by forming the regenerating unit 350 on the damaged top layer 320. In this case, a boundary having a distinct color may be generated between the regenerating unit 350 and the damaged top layer 320, as compared with the boundaries between other superposed layers 320 and 330, 330 and 340, and 340 and 320. This may be a phenomenon generated by the difference between a case when a next layer is superposed in a state where the high temperature is maintained in the chamber and a case when the layer is taken out from the chamber to be cooled down and then a next layer is superposed thereon, during the process of superposing layers. According to an aspect of the present invention, the damaged top layer 320 is previously processed to be planarized and then the regenerating unit 350 is formed thereon. Further, according to another aspect of the present invention, before forming the regenerating unit, a pre-cleaning process may be included before or after, or before and after the pre-processing, to remove impurities generated on the surface.

In the meantime, the component for fabricating an SiC semiconductor having a plurality of layers having different transmittances according to an aspect of the present invention may further include a plasma resistant material in addition to SiC. The component for fabricating an SiC semiconductor may be used in an environment in which the component is exposed to the plasma to be etched and damaged. Therefore, when the component is damaged, the replacement is necessarily followed. In order to save the production cost of the semiconductor product due to frequent replacement, the non-regenerating unit, or the regenerating unit, or the non-generating unit and the generating unit may further include an additional plasma resistant material.

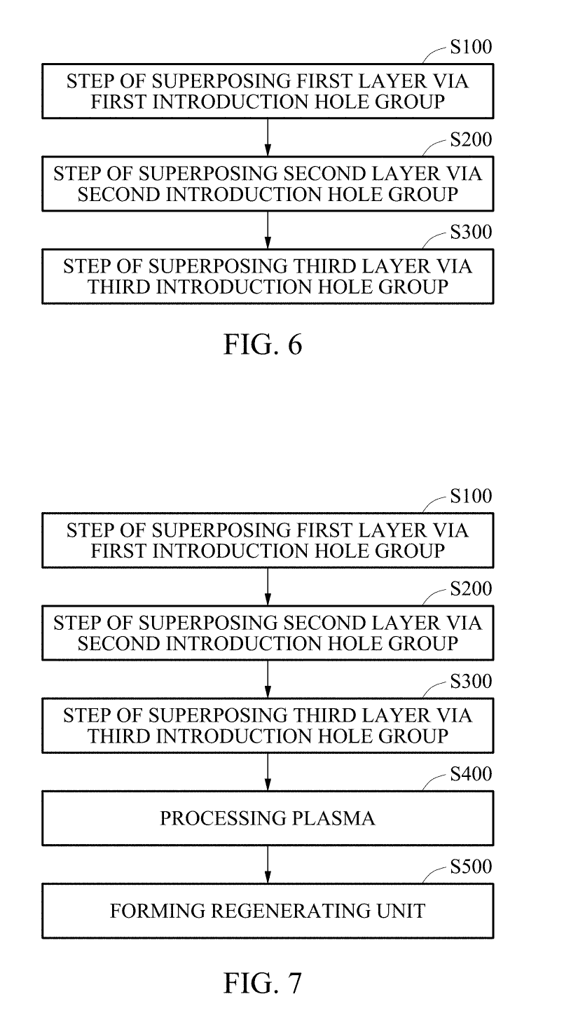

FIG. 6 is a view of a process of manufacturing a component for fabricating an SiC semiconductor having a plurality of layers having different transmittances according to an exemplary embodiment of the present invention. In the following description, a manufacturing method of a component for fabricating an SiC semiconductor having a plurality of layers having different transmittances according to an exemplary embodiment of the present invention will be described with reference to the view of FIG. 6.

According to another exemplary embodiment of the present invention, provided is a manufacturing method of a component for fabricating an SiC semiconductor having a plurality of layers having different transmittances including a step S100 of superposing a first layer containing SiC using a first introduction hole group including some of a plurality of raw material gas injecting introduction holes in a chemical vapor deposition chamber including a plurality of raw material gas injecting introduction holes and a step S200 of superposing a second layer containing SiC using a second introduction hole group including the others of the plurality of raw material gas injecting introduction holes.

A component for fabricating an SiC semiconductor according to the present invention may be manufactured by a chemical vapor deposition method in a chemical vapor deposition chamber. In this case, a raw material gas which forms each layer may be supplied through the plurality of raw material gas injecting introduction holes. As long as the plurality of raw material gas injecting introduction holes uniformly superposes each layer, the location in the chemical vapor deposition chamber and the number of raw material gas injecting introduction holes are not specifically limited in the present invention. However, according to an aspect of the present invention, some of the plurality of introduction holes may be configured as a first introduction hole group and the others may be configured as a second introduction hole group. Further, according to another aspect of the present invention, some of the other introduction holes other than the first introduction hole group and the second introduction hole group may be configured as a third introduction hole group or a fourth introduction hole group. Further, each of the introduction hole groups may be configured to repeatedly include some of introduction holes.

Different introduction hole groups formed as described above may be used to superpose layers. According to an aspect of the present invention, a step of superposing a first layer containing SiC using a first introduction hole group and a step of superposing a second layer containing SiC using a second introduction hole group may be included. By doing this, the first layer and the second layer which are generated using introduction hole groups which are injected in different locations may be formed to have different transmittances.

Similarly, in this case, the third layer may be formed to have a different transmittance from that of the second layer which is adjacent thereto. In the meantime, according to an aspect of the present invention, after the step of superposing the second layer, a step of superposing a third layer containing SiC using the first introduction hole group again may be further included. In this case, the first layer, the second layer, and the third layer may form a sandwiched structure. Further, according to an aspect of the present invention, after the step of superposing the third layer, a step of further superposing a fourth layer, a fifth layer, and a sixth layer may be included.

In FIG. 5 described above, a structure manufactured using the first introduction hole group which has been used to superpose the first layer 320 to use the fourth layer 320 is illustrated. In the first layer and the fourth layer formed as described above, a transmittance, or a color, or a transmittance and a color may be the same.

According to an example of the present invention, between the steps of superposing the layers, the component for fabricating an SiC semiconductor may be maintained in the chemical vapor deposition chamber. The step of superposing adjacent layers is formed using different introduction hole groups and the component for fabricating an SiC semiconductor is maintained in the chemical vapor deposition chamber during the process of changing introduction hole groups to be used. By doing this, a surface temperature of the component for fabricating an SiC semiconductor is not lowered during the process of changing introduction hole groups to be used. Therefore, even though the process of superposing layers by changing introduction holes is included, an efficiency of a production process of the component for fabricating an SiC semiconductor may be maintained without increasing the temperature again. Further, due to this process, the component containing SiC of the adjacent different layer is superposed while the superposed layer is not completely cooled so that the color may be gradually changed at the boundary with the adjacent layer. According to an example of the present invention, the locations of individual introduction hole groups may vary in the chemical vapor deposition chamber. As long as the plurality of raw material gas injecting introduction holes uniformly superposes each layer, the location in the chemical vapor deposition chamber and the number of raw material gas injecting introduction holes are not specifically limited in the present invention. However, as described above, the configuration of introduction holes included in the first introduction hole group, the second introduction hole group, and more introduction hole groups are not totally the same so that the locations of the introduction hole groups may be different from each other. By doing this, the layers which are generated using introduction hole groups which are injected in different locations may be formed to have different transmittances from those of adjacent layers.

According to an example of the present invention, times to perform the steps of superposing layers may vary. The step of superposing individual layers of the present invention may be controlled by an operation time of the injecting introduction hole as needed. In this case, a time to exchange the introduction holes and superpose a different layer may be set by controlling the operation time of the injecting introduction hole. Further, according to an aspect of the present invention, the steps of superposing the layers may be controlled through a flow rate of the injecting introduction hole. When the time to inject the introduction hole group and a flow rate are set to be the same, each layer may be formed to have the same thickness. In the meantime, according to an aspect of the present invention, times to perform the steps of superposing layers may be configured to be different from each other as needed. In this case, the layers may have different thicknesses.

FIG. 7 is a view of a process of manufacturing a component for fabricating an SiC semiconductor having a plurality of layers having different transmittances according to another exemplary embodiment of the present invention.

According to an example of the present invention, a step S400 of processing plasma on the component for fabricating an SiC semiconductor in a dry etching device and a step S500 of forming a regenerating unit containing SiC on at least a part of the superposed layer of the component for fabricating an SiC semiconductor may be further included. A part of the component for fabricating an SiC semiconductor which is exposed to the plasma may be etched by the step of processing plasma in the dry etching device. The etching process may be a major cause of degradation of the quality of semiconductor components to be manufactured so that replacement needs to be carried out at an appropriate time. According to an aspect of the present invention, after the step of processing plasma, a step of forming a regenerating unit containing SiC on at least a part of the superposed layer including a part which is exposed to the plasma to be etched may be further included. By doing this, a regenerated product for manufacturing an SiC semiconductor may be manufactured instead of the replacement with a new product in accordance with an appropriate replacement cycle.

According to an example of the present invention, an average thickness of the regenerating unit may be 0.1 mm to 3 mm. A replacement cycle of the component for fabricating a semiconductor used in a reaction vessel which is exposed to the plasma may be determined by identifying the etched degree. In this case, when the etched degree is approximately 1 mm in average, the replacement may be considered to be replaced in consideration of the quality of the semiconductor product to be manufactured. In this case, in order to form a regenerating unit which is used instead of replacement with a new product, a regenerating unit having a thickness which is larger than an etched thickness needs to be formed. Therefore, according to an aspect of the present invention, an average thickness of the regenerating unit may be 0.1 mm to 3 mm.

According to an example of the present invention, between the step of processing plasma and the step of forming a regenerating unit, a step of pre-processing the component for fabricating an SiC semiconductor or a step of pre-cleaning the component for fabricating an SiC semiconductor or both the steps may be further included.

According to an aspect of the present invention, the uniform deposition may be induced in the step of forming the regenerating unit thereafter through the pre-processing step which planarizes a portion which is unevenly etched to be damaged. In the present invention, the process of the step of pre-processing is not specifically limited so that all processes which uniformly process a portion where a regenerating unit is deposited to be formed may be included. According to another aspect of the present invention, a surface impurity may be removed during a pre-cleaning step. In the present invention, the process of the step of pre-cleaning is not specifically limited but the surface impurities may be removed using acid or base solution or an ultrasonic wave.

According to an example of the present invention, after the step of forming the regenerating unit, a step of post-processing the formed regenerating unit, a step of post-cleaning the regenerating unit, or both the steps may be included.

According to an aspect of the present invention, the regenerating unit is deposited during the post-processing step so that the component for fabricating an SiC semiconductor having a larger thickness may be standardized. In this case, since a material such as SiC which is hard to be processed may be deposited on the regenerating unit, it may be very important to ensure the productivity of the product by minimizing a direct processing area during the standardization process through the post-processing step. According to another aspect of the present invention, in order to ensure the convenience in the post-processing step, a configuration to mask a portion of the component for fabricating a semiconductor damaged during the step of forming the regenerating unit may be included. In the present invention, the process of the post-processing step is not specifically limited so that all processes which standardize a portion where a regenerating unit is deposited may be included.

According to another aspect of the present invention, a surface impurity may be removed during a post-cleaning step. In the present invention, the process of the post-cleaning step is not specifically limited but the surface impurities may be removed using acid or base solution or ultrasonic wave.

Although the exemplary embodiments have been described above by a limited example and the drawings, various modifications and changes can be made from the above description by those skilled in the art. For example, even when the above-described techniques are performed by different order from the described method and/or components described above are coupled or combined in a different manner from the described method or replaced or substituted with other components or equivalents, the appropriate results can be achieved.

Therefore, other implements, other embodiments, and equivalents to the claims are within the scope of the following claims.

What is claimed is:

1. A component for fabricating an SiC semiconductor having a plurality of layers having different transmittances, the component comprising two or more superposed layers, wherein each of superposed layers contains SiC and has a transmittance value different from that of another adjacent layer,
wherein a color is gradually changed at a boundary of superposed layers.

2. (canceled)

3. The component for fabricating an SiC semiconductor of claim 1, wherein compositions of the superposed layers are the same.

4. The component for fabricating an SiC semiconductor of claim 1, wherein the superposed layers are superposed on a graphite base material.

5. The component for fabricating an SiC semiconductor of claim 1, wherein interception of growth of one or more abnormal crystals is included in the boundary of superposed layers.

6. The component for fabricating an SiC semiconductor of claim 1, wherein the component for fabricating a semiconductor is a component of a plasma processing device and includes at least one selected from a group consisting of a ring, an electrode, and a conductor.

7. The component for fabricating an SiC semiconductor of any one of claim 1, further comprising:
a regenerating unit containing SiC formed on at least a part of the superposed layer.

8. The component for fabricating an SiC semiconductor of claim 7, wherein colors between the regenerating unit containing SiC and a superposed layer adjacent to the regenerating unit are different.

9. A manufacturing method of a component for fabricating an SiC semiconductor of claim 1, the method comprising:
in a chemical vapor deposition chamber including a plurality of raw material gas injecting introduction holes,
superposing a first layer containing SiC using a first introduction hole group including some of the plurality of raw material gas injecting introduction holes; and
superposing a second layer containing SiC using a second introduction hole group including the other some of the plurality of raw material gas injecting introduction holes.

10. The manufacturing method of claim 9, further comprising:
superposing a third layer containing SiC using a third introduction hole group after the superposing of a second layer.

11. The manufacturing method of claim 9, wherein between the superposing of layers, the component for fabricating an SiC semiconductor is maintained in the chemical vapor deposition chamber.

12. The manufacturing method of claim 9, wherein in the chemical vapor deposition chamber, locations of the introduction hole groups are different.

13. The manufacturing method of claim 9, wherein times to perform the superposing of layers are different.

14. A manufacturing method of a component for fabricating an SiC semiconductor, the method comprising:
in a chemical vapor deposition chamber including a plurality of raw material gas injecting introduction holes,
superposing a first layer containing SiC using a first introduction hole group including some of the plurality of raw material gas injecting introduction holes; and
superposing a second layer containing SiC using a second introduction hole group including the other some of the plurality of raw material gas injecting introduction holes,
processing plasma on the component for fabricating an SiC semiconductor in a dry etching device; and
forming a regenerating unit containing SiC on at least a part of the superposed layer of the component for fabricating an SiC semiconductor,
wherein the first layer and the second layer have a different transmittance value,
wherein a color is gradually changed at a boundary between the first layer and the second layer.

15. The manufacturing method of claim 14, wherein an average thickness of the regenerating unit is 0.1 mm to 3 mm.

16. The manufacturing method of claim 14, further comprising:
between the processing of plasma and the forming of a regenerating unit,
processing the component for fabricating an SiC semiconductor, a pre-cleaning step, or both the processing and the pre-cleaning step.

17. The manufacturing method of claim 14, further comprising:
after the forming of a regenerating unit,
a post-processing step of the formed regenerating unit, a post-cleaning step, or both the steps.
